(19) United States
(12) Patent Application Publication
(10) Pub. No.: US 2025/0372162 A1
(43) Pub. Date: Dec. 4, 2025

(54) LOW-POWER TWO-PORT STATIC RANDOM ACCESS MEMORY

(71) Applicant: UNTETHER AI CORPORATION, Toronto (CA)

(72) Inventor: Katsuyuki SATO, Tokyo (JP)

(21) Appl. No.: 19/224,147

(22) Filed: May 30, 2025

Related U.S. Application Data
(60) Provisional application No. 63/654,173, filed on May 31, 2024.

(51) Int. Cl. G11C 11/419

(52) U.S. Cl. CPC G11C 11/419

(57) ABSTRACT

A low-power two-port static random access memory (2P-SRAM) for at-memory architecture is set forth. Each column has a latch which is controlled by Latch_EN signal which is generated by monitoring the discharge speed of dummy read bit line (dummy RBL). The write scheme uses boosted write word line with only a short MOS between write bit line (WBL) and write bit line bar (/WBL) to generate half Vdd write bit line precharge. The read word line voltage is supplied by adaptive voltage supply which can compensate process and temperature variation. The segmented number of WBL is equal or larger than that of RBL.

### BACKGROUND OF THE INVENTION

The present invention is directed to two-port static random access memory (hereinafter 2P-SRAM), and more particularly to an on-chip 2P-SRAM that is located between High Bandwidth DRAM (HBM) and an Artificial Intelligence (AI) or video processing chip.

A 2P-SRAM is a type of random access memory that supports multiple reads or writes occurring at the same time at different addresses within the memory. Simultaneous or parallel read/write (R/W) access 2P-SRAM is widely employed in embedded multimedia and communication applications.

There is a recognized need to reduce power dissipation in traditional 2P-SRAMs (e.g. Vdd supply voltage of 0.75 V or less), wherein a plurality of memory cells along a selected write and read word-line are read and written via a pair of write bit lines (WBL and/WBL) and a single read bit line (RBL). Recently, this need has become more pressing with the introduction of large HBM to Al and video processing chips using 2D or 3D integration, wherein buffer memory is used to adjust for frequency difference between the HBM and Al or video processing chip.

### BRIEF DESCRIPTION OF THE DRAWINGS

FIG. 1 shows a conventional 8T 2P-SRAM bit cell, according to the prior art.

FIG. 2 shows an 8T 2P-SRAM bit cell with bit line keeper, according to the prior art.

FIG. 3 shows a 10T 2P-SRAM bit cell with differential sensing, according to the prior art.

FIG. 4 shows a 2P-SRAM operating as a buffer between HBM and an Al or video processing chip, according to an embodiment.

FIG. 5 shows an 8T 2P-SRAM bit cell with dummy column circuit and circuit for generating a latch enable signal (Latch_EN), according to an embodiment.

FIG. 6 shows an 8T 2P-SRAM bit cell with column circuit with a latch.

FIG. 7 shows a 2P-SRAM with dummy column circuit of FIG. 5 and parallel 8T 2P-SRAM bit cells of FIG. 6, with WBL and RBL segmentation.

FIG. 8 shows an adaptive voltage supply for generating a RWL signal for discharge speed detection in the dummy column circuit of FIG. 5.

FIG. 9A shows a pseudo differential amplifier (PDA) to amplify the RBL signal, using a reference voltage generator, according to an embodiment.

FIG. 9B is a diagram showing how the reference voltage is set, according to an embodiment.

FIG. 9C is a timing diagram for operation of the PDA in FIG. 9A.

FIG. 10A is a representation of inadequate RBL discharge without the PDA of FIG. 9A.

FIG. 10B is a representation of fast RBL discharge using the PDA of FIG. 9A.

### DESCRIPTION OF THE RELATED ART

A number of techniques are known in the art for write assist and for improving read stability in 2P-SRAM.

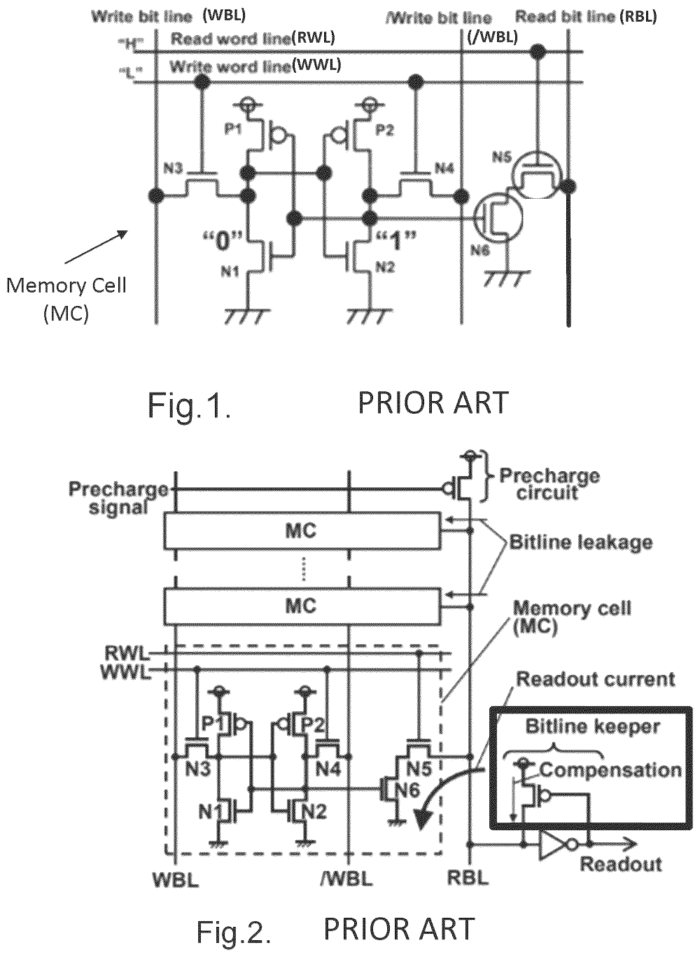

Regarding write assist, FIG. 1 shows a standard 8T 2P-SRAM, according to D. P. Wang, et al, “A 45 nm Dual-Port SRAM with Write and Read Capability Enhancement at Low Voltage,” SOC Conference, 2007 IEEE International. The standard 8T 2P-SRAM cell includes a pair of complementary write bit lines (WBL and/WBL), a read bit line (RBL), a write word line (WWL), and a read word line (RWL), for implementing a negative bit line (BL) scheme for write assist.

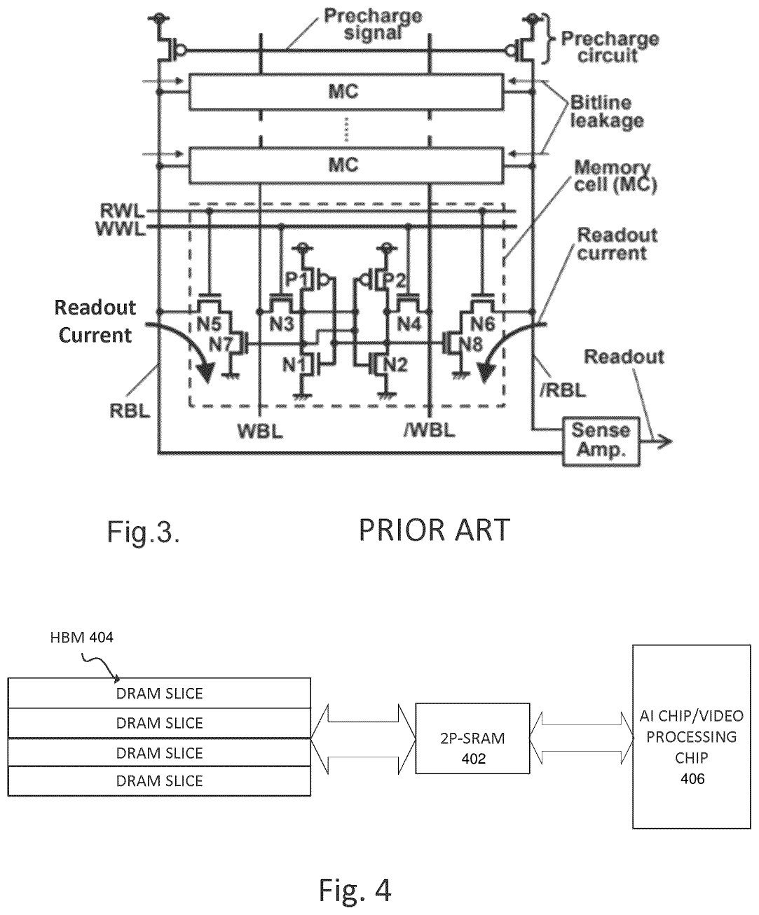

Regarding read stability, FIG. 2 shows a bit line keeper to keep the RBL at a high state and protect against leaks during data read out, as described in Hiroki Noguchi et al, “Which is the Best Dual-Port SRAM in 45-nm Process Technology?—8T, 10T Single End, and 10T Differential—,” Conference on Integrated Circuit Design and Technology and Tutorial, 2008 IEEE International. However, this results in a lower RBL discharge speed, and a larger delay overhead as a supply voltage (VDD) decreases due to operation of the bit line keeper. Although the bit line keeper of FIG. 2 can compensate for leakage of the high-level BL, especially when the frequency is low, it slows the discharge speed of low-level BL, thereby reducing the design margin.

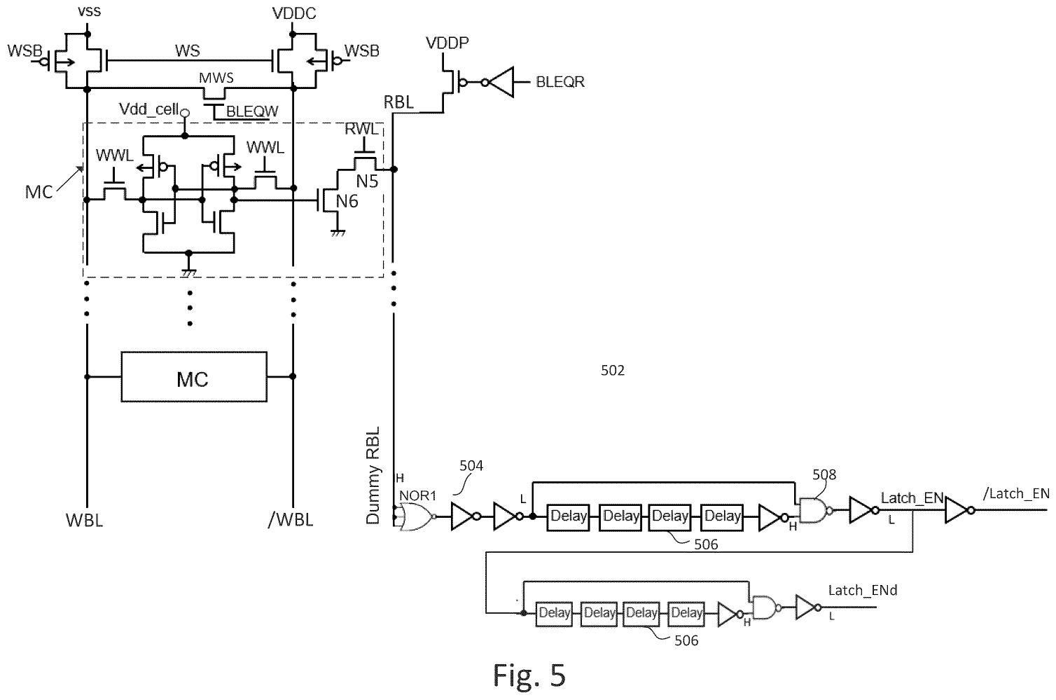

Another technique for improving read stability is described in Hiroki Noguchi et al, where a differential sensing scheme is used for a 10T bit cell, as shown in FIG. 3. Differential sensing provides faster sensing speed than single RBL discharge sensing but requires precharging the differential bit lines to VDD before the start time of a clock cycle.

### SUMMARY

It is an object of the present invention to provide a 2P-SRAM bit cell with robust read scheme that does not require a bit line keeper.

According to an aspect of an embodiment of the invention, a 2P-SRAM is provided for an at-memory architecture with a processing element (PE) and/or in a buffer memory bridging an Al chip and external DRAM. The 2P-SRAM includes a latch to read data from the read bit line (RBL) of every column of the SRAM and a dummy column circuit for monitoring the discharge speed of RBL and generating a latch enable signal (Latch_EN) for each latch.

### DETAILED DESCRIPTION

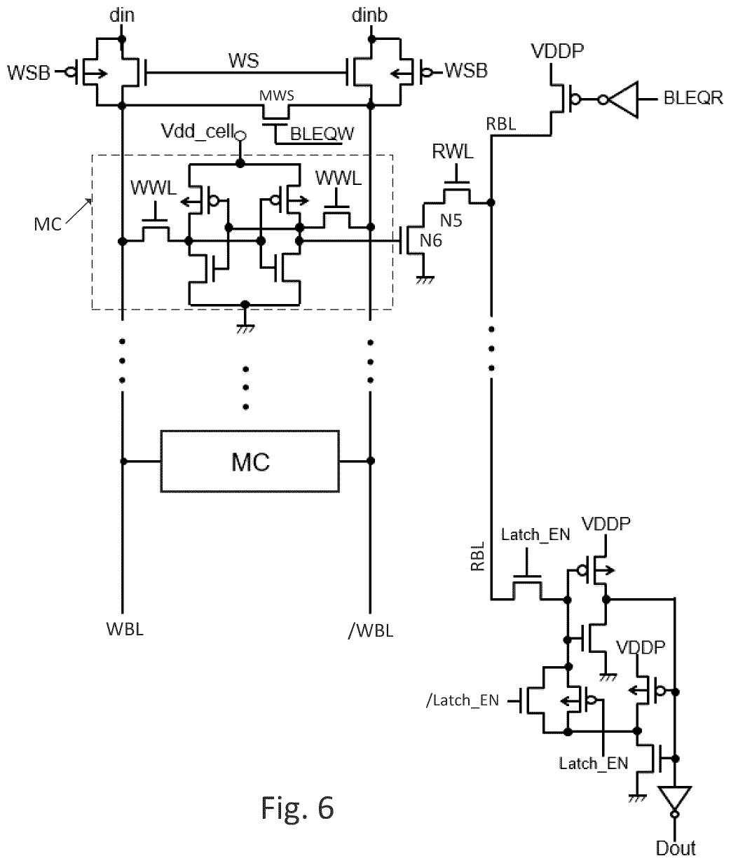

As shown in FIG. 4, according to an embodiment, an on-chip 2P-SRAM 402 is provided between High Bandwidth DRAM (HBM) 404 and an Artificial Intelligence (AI) or video processing chip 406. The 2P-SRAM 402 operates as a buffer memory to adjust for frequency difference between the HBM 404 and the Al/video processing chip 406. The 2P-SRAM 402 is used as a buffer memory because write and read operations can occur simultaneously, which results in high throughput of data from the HBM 404 to the Al/video processing chip 406. However, as discussed above, it is an object of the present invention to provide 2P-SRAM having a robust read scheme that does not require a bit line keeper.

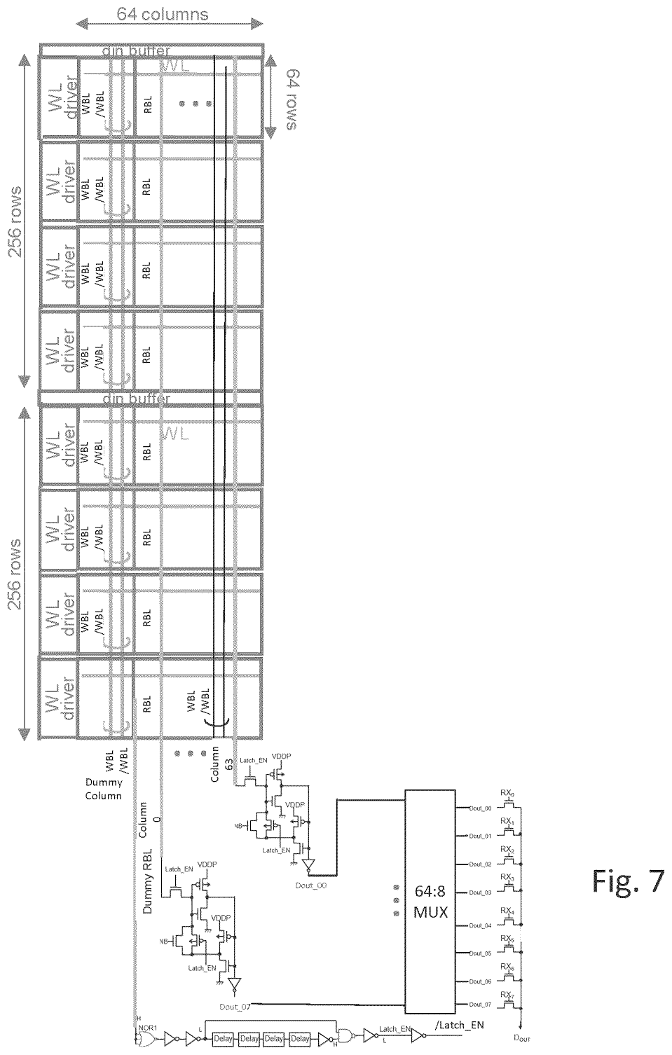

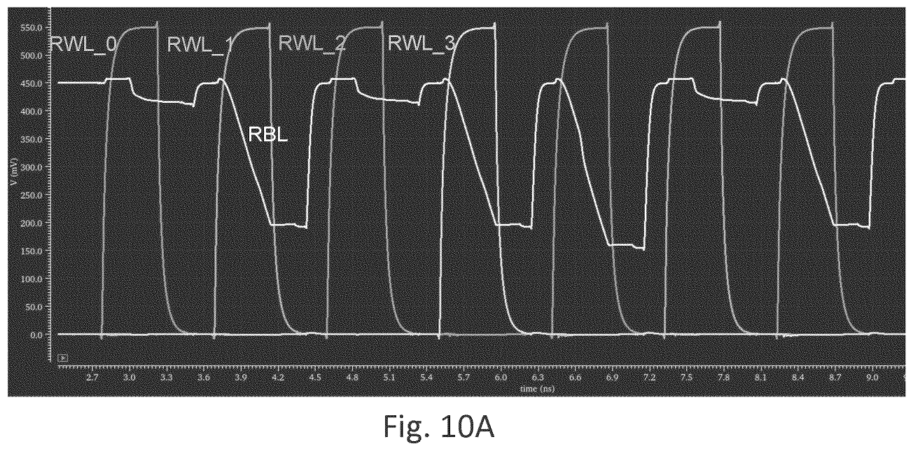

As shown in FIG. 5, a self-timed out circuit in accordance with an embodiment is illustrated generally. The self-timed circuit monitors the RBL (Read bit line) discharge speed using a RBL of a dummy column circuit 502. The dummy column circuit 502 includes a dummy RBL, an input logic gate 504 configured operate at a predefined threshold voltage, a plurality of delay gates 506, and an output logic gate 508. In some embodiments, the input logic gate 504 is a NOR gate. In some embodiments, the NOR gate is followed by a serial pair of inverters. In some embodiments, the output logic gate 508 is a NAND gate followed by an inverter. The dummy RBL signal is coupled to the inputs of the input logic gate 504. The output signal of the input logic gate 504 is delayed by delay gates 506. The output signal from the delay gates 506 is combined with the output signal from the input logic gate 504 at the output logic gate 508. The output of the output logic gate 508 is a latch enable signal Latch_EN. The latch enable signal Latch_EN is further inverted to provide a complementary latch enable signal/Latch_EN. In some embodiments, the latch enable signal Latch_EN is delayed by a plurality of delay gates 506 to provide a delayed latch enable signal Latch_ENd. The delayed latch enable signal Latch_ENd is used as a control input to a pseudo differential amplifier illustrated in FIG. 9A.

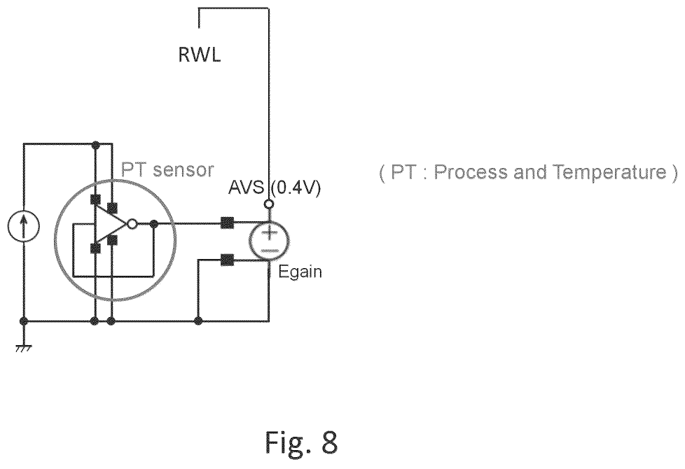

When the RWL (Read word line) is activated, the dummy RBL starts discharging, such that when the RBL voltage falls below the logic threshold of the NOR gate, a Latch_EN signal is generated. The Latch_EN signal transfers RBL data to Dout through a latch, as shown in FIG. 6. The Latch_EN signal is de-asserted by a self-time out, so that the duration of time that high data on RBL is maintained is from RWL turn-on to the Latch_EN de-assertion, which is independent of frequency, Therefore, there is no need for a bit line keeper.

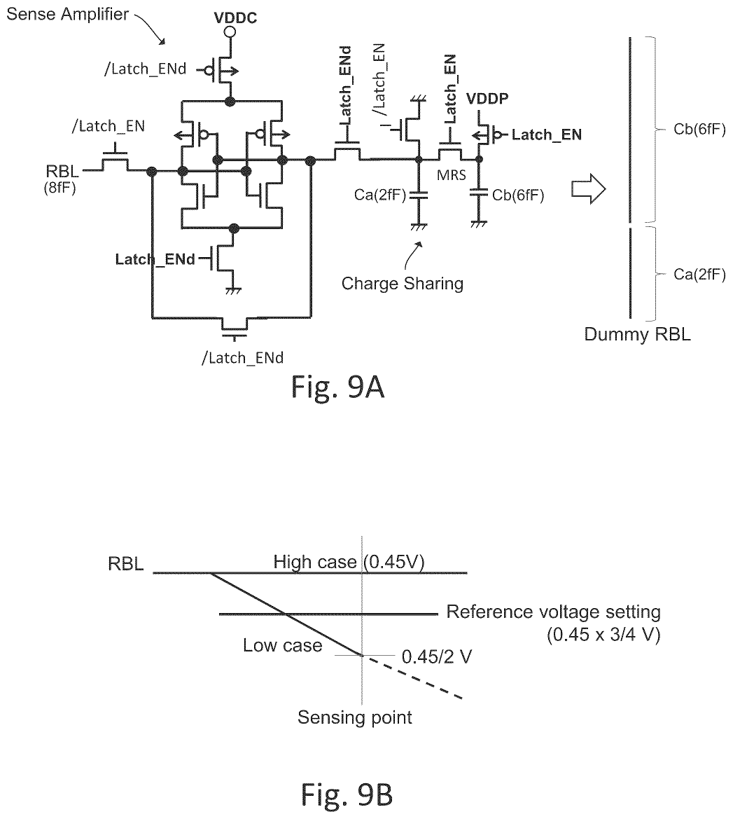

RBL discharge speed is determined by RBL capacitance, RBL precharge level, and the voltage level of RWL. As shown in FIG. 7, RBL capacitance can be reduced by RBL segmentation. As shown in FIG. 7, the WBL (Write bit line) is also segmented, but since the WBL is driven by write buffer (din_buffer) whose drivability is larger than the RBL discharge speed, WBL segmentation will be less than RBL segmentation.

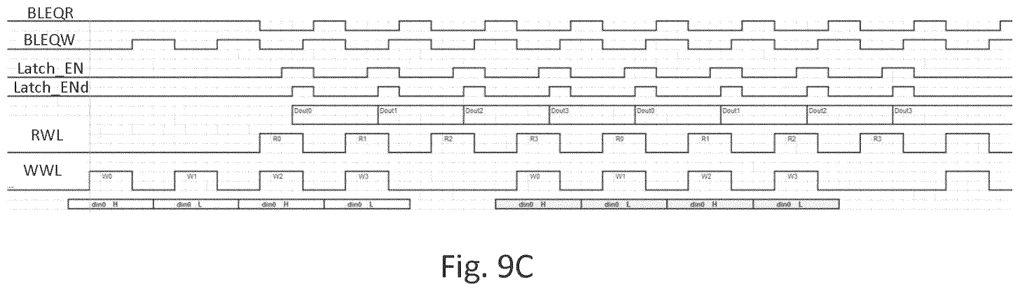

The RBL precharge level is set to the same voltage as the PE (Processing Element) in the at-memory architecture. An adaptive voltage supply (AVS) is set forth to provide RWL voltage to compensate for process and temperature variations, that is, when slow corners such as a process slow corner and/or low temperature is present, RWL voltage will be set higher than normal. An exemplary AVS circuit is shown in FIG. 8.

Even if RWL voltage is increased in slow corners by the AVS of FIG. 8, there is a limitation to the discharge speed of RBL by N5 and N6 of FIG. 5, to within a finite time. For this case, it is an aspect of the present disclosure to provide a pseudo differential amplifier to amplify RBL, as shown in FIG. 9A. The pseudo differential amplifier of FIG. 9A includes a differential sense amplifier and a charge sharing circuit, as discussed below.

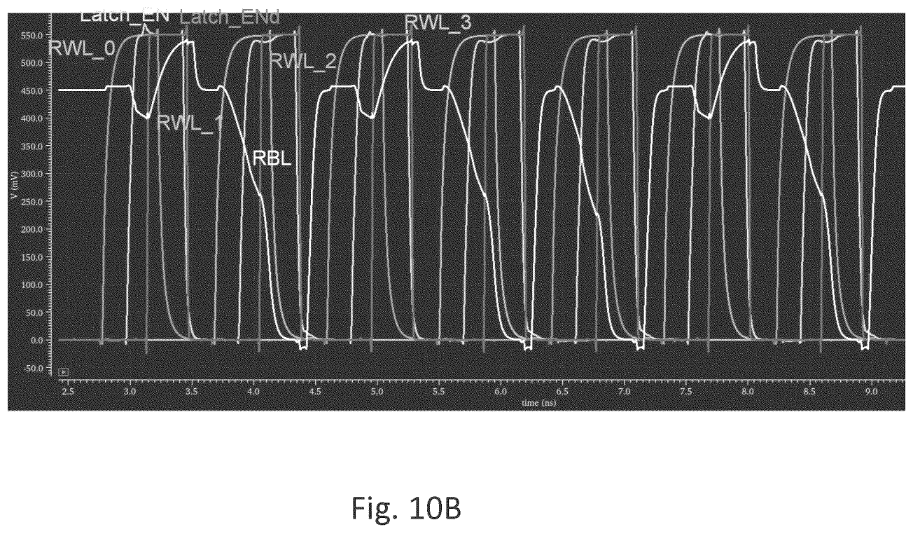

Since 2P-SRAM has a single RBL, to amplify a single RBL, a reference voltage is generated by the charge sharing circuit for the differential sense amplifier to amplify the RBL. As shown in FIG. 9B, the reference voltage is set by charge sharing. Supposing that RBL capacitance is 8fF and RBL is precharged at 0.45V, the dummy RBL is used as the reference node, and is divided into 3:1, that is, 6fF: 2fF to obtain ¾ of 0.45V by charge sharing. Since the high level of RBL is 0.45V, and a low level of RBL is assumed 0.45/2 V, ¾ is therefore the middle of 0.45V and 0.45/2V, as shown in FIG. 9B. Before charge sensing, 6fF of the dummy RBL is precharged at 0.45V, and 2fF of the dummy RBL is precharged at 0V, and then 6fF and 2fF are short circuited by a short Metal Oxide Semiconductor (MOS) read transistor MRS, as shown in FIG. 9A, resulting in 0.45V×¾, which is the middle of 0.45V and 0.45/2V, that is, the reference voltage as shown in FIG. 9B. A timing diagram for operation of the pseudo differential amplifier of FIG. 9A, is shown in FIG. 9C. The effectiveness of fast RBL discharge using the PDA of FIG. 9A is demonstrated in FIG. 10B as compared to inadequate RBL discharge without the PDA of FIG. 9A, as shown in FIG. 10A.

For writing to the 2P-SRAM of the present invention, a conventional negative write bias scheme can be used, as described in D. P. Wang, et al, “A 45 nm Dual-Port SRAM with Write and Read Capability Enhancement at Low Voltage,” SOC Conference, 2007 IEEE International, which needs a charge pump capacitor at every column. However, in order to avoid forward bias of the NMOS substrate due to the negative bias, according to an aspect of an embodiment, a WWL (Write Word Line) boost is used as a write assist (i.e. larger than bit cell voltage), with only a short MOS between WBL (Write bit line) and/WBL. In particular, as discussed in T. Sano, et al, “Dual port SRAM”, JP 6802313 B2 2020.12.16, a short MOS can be provided between WBL and/WBL, and a Vdd supply MOS can be connected to WBL as a precharge level. However, as shown in FIG. 5, the Vdd supply MOS to WBL of T. Sano, et al, can be eliminated because only a short write MOS MWS is required for short circuiting WBL and/WBL upon receipt of the BLEQW enable signal, as shown in FIG. 6, resulting in a half Vdd precharge level, that contributes to low power consumption.

These together with other aspects and advantages which will be subsequently apparent, reside in the details of construction and operation as more fully hereinafter described and claimed, reference being had to the accompanying drawings forming a part hereof, wherein like numerals refer to like parts throughout.

What is claimed is:

1. A two-port static random-access memory (2P-SRAM) embedded in an at-memory architecture, comprising:
a plurality of memory cells each having a write word line, a pair of write bit lines and a read bit line;
a dummy column circuit for monitoring discharge speed of a single read bit line of a single column of the plurality of memory cells and in response generating a latch enable signal when the single read bit line discharges below a threshold voltage; and
a plurality of latches for reading the read bit line of corresponding ones of each other column of the plurality of memory cells in response to receiving the latch enable signal.

2. The 2P-SRAM of claim 1, further including a short write MOS transistor between the pair of write bit lines voltage for short circuiting the pair of write bit lines voltage to provide a write assist boost voltage larger than a bit cell voltage when writing to the memory cells.

3. The 2P-SRAM of claim 2, wherein the pairs of write bit line and read bit lines in the plurality of memory cells are segmented such that write bit line segmentation is less than read bit line segmentation.

4. The 2P-SRAM of claim 1, further including an adaptive voltage supply for generating an enable signal for discharge speed detection on the single read bit line of the dummy column circuit.

5. The 2P-SRAM of claim 1, further including a pseudo differential amplifier (PDA) for read bit line amplification using a reference voltage generated by charge sharing of the single read bit line of the dummy column circuit segmented into two portions.

6. The 2P-SRAM of claim 5, wherein the pseudo difference amplifier includes a sense amplifier circuit for amplifying the single read bit line and a charge sharing circuit for providing a reference voltage to the sense amplifier circuit.

7. The 2P-SRAM of claim 6, wherein the charge sharing circuit includes two portions having a 3:1 capacitance ratio, the portions being selectively coupled by a short read MOS transistor to provide the reference voltage.
